(19) United States
(12) Patent Application Publication
(10) Pub. No.: US 2022/0235486 A1
(43) Pub. Date: Jul. 28, 2022

(54) Graphite Plate

(71) Applicant: ENKRIS SEMICONDUCTOR, INC., Suzhou (CN)

(72) Inventor: Peng XIANG, Suzhou (CN)

(73) Assignee: ENKRIS SEMICONDUCTOR, INC., Suzhou (CN)

(21) Appl. No.: 17/582,188

(22) Filed: Jan. 24, 2022

(30) Foreign Application Priority Data
Jan. 25, 2021 (CN) 202120203604.1

(51) Int. Cl. C30B 25/12; C23C 16/458

(52) U.S. Cl. CPC C30B 25/12; C23C 16/4586

(57) ABSTRACT

Disclosed is a graphite plate to solve a problem of poor performance uniformity of an epitaxial wafer obtained by using a graphite plate for epitaxial growth. The graphite plate includes a graphite plate body, the graphite plate body includes a carrying recess, and at least part of the inner wall of the carrying recess is covered with a heat insulation material.

### CROSS-REFERENCE TO RELATED APPLICATIONS

This application claims priority to Chinese Patent Application No. 202120203604.1, filed on Jan. 25, 2021, which is hereby incorporated by reference in its entirety.

### TECHNICAL FIELD

The present application relates to the technical field of semiconductor material growth, more particular, to a graphite plate.

### BACKGROUND

A Light Emitting Diode (LED) is a solid-state semiconductor diode light-emitting device, which is widely used in lighting fields such as indicator light, display screens, etc. At the present stage, a method of producing LED wafers is mainly realized by metal-organic chemical vapor deposition (MOCVD), and it's process may be briefly described as follows: a substrate is placed into a recess of a graphite plate, the graphite plate loaded with the substrate is placed into the MOCVD reaction chamber, the reaction chamber temperature is heated to a preset temperature, and an organic metal compound and group V gases are input, so that a chemical bond thereof may be broken on the substrate and re-polymerize to form a LED epitaxial layer.

However, an epitaxial wafer obtained according to the above process has poor performance uniformity, such as, uneven LED wavelength, uneven two-dimensional electron gas, etc.

### SUMMARY

In view of this, embodiments of the present application are devoted to providing a graphite plate to solve a problem of poor performance uniformity of an epitaxial wafer obtained by using a graphite plate for epitaxial growth.

The application provides a graphite plate, including a graphite plate body, the graphite plate body includes a carrying recess, and at least part of the inner wall of the carrying recess is covered with a heat insulation material. By providing a heat insulation material at a preset position (such as a high temperature position) of the carrying recess, the temperature difference between different positions of the inner wall of the carrying recess is decreased, so that a substrate can be evenly heated.

In an embodiment, a central area of a bottom wall of the carrying recess is covered with the heat insulation material. Through research, the inventor found that the temperature of the central area of the carrying recess is higher than that of other areas. Therefore, by providing the heat insulation material at the central area, it may be more targeted to balance the temperatures at various positions of the inner wall of the carrying recess.

In an embodiment, the bottom wall includes a recess, and the heat insulation material is filled in the recess, a surface of the heat insulation material is flush with the bottom wall. Thus, compared with directly forming the heat insulation material on the bottom wall surface of the carrying recess, it can ensure that the supporting surface of the carrying recess is a flat surface, so as to achieve a better supporting effect.

In an embodiment, the bottom wall of the carrying recess is a flat surface, the central area of the bottom wall includes a plurality of support areas spaced apart from each other, and each of the support areas is covered with the heat insulation material. Thus, due to the thickness of the heat insulation material, a support frame structure may be formed on the bottom wall of the carrying recess and the substrate placed in the carrying recess is arranged overhead by the support frame structure, thus avoiding that the corresponding local area of the substrate caused by the central area of the carrying recess is overheated.

In an embodiment, each of the support areas is provided with a protrusion, and the protrusion is covered with the heat insulation material. By providing the protrusions with the heat insulation material, a support frame structure may be formed on the bottom wall of the carrying recess, and the substrate placed in the carrying recess is arranged overhead by the support frame structure, thus avoiding the corresponding local area of the substrate caused by the central area of the carrying recess is overheated.

In an embodiment, the plurality of support areas are annularly arranged on the bottom wall. Thus, it is possible to ensure that a plurality of heat insulation materials form a stable support frame structure to provide stable support.

In an embodiment, at least part of sidewall of the carrying recess is covered with the heat insulation material.

In an embodiment, a part of the sidewall of the carrying recess away from a center of the graphite plate body is covered with the heat insulation material. Since the substrate located in the carrying recess is subjected to centrifugal force during the rotation of the graphite plate, the edge region of the substrate away from the center of the graphite plate body is always in contact with the inner wall of the carrying recess, which tends to cause higher temperature at the contact position than at other position of the sidewall of the substrate. Therefore, by providing the heat insulation material on the sidewall, the heating of the substrate may be further balanced, thereby improving the performance uniformity of the epitaxial wafer.

In an embodiment, a thickness of the heat insulation material ranges from 0.1 micron to 100 microns.

In an embodiment, a material of the heat insulation material includes any one of following materials: aluminum oxide, silicon oxide and silicon nitride.

According to the graphite plate provided by the present application, by providing a heat insulation material at a preset position of the carrying recess, such as a high temperature position, the temperature difference between different positions of the inner wall of the carrying recess is decreased, so that a substrate can be evenly heated.

### BRIEF DESCRIPTION OF DRAWINGS

FIG. 1 is a schematic diagram of a structure of a graphite plate provided by the first embodiment of the present application.

FIG. 2 is a cross-section diagram of the graphite plate as shown in FIG. 1.

FIG. 3 is a cross-section diagram of a graphite plate provided by the second embodiment of the present application.

FIG. 4 is a schematic diagram of a structure of a graphite plate provided by the third embodiment of the present application.

FIG. 5 is a schematic diagram of the cross-sectional structure of the graphite plate along the line A₁A₂ as shown in FIG. 4.

FIG. 6 is a cross-section diagram of a graphite plate provided by the fourth embodiment of the present application.

FIG. 7 is a cross-section diagram of a graphite plate provided by the fifth embodiment of the present application.

FIG. 8 is a schematic diagram of a structure of a graphite plate provided by the sixth embodiment of the utility model.

FIG. 9 is a sectional view of the graphite plate shown in FIG. 8.

FIG. 10 is a sectional view of a graphite plate provided by the seventh embodiment of the utility model.

FIG. 11 is a sectional view of a graphite plate provided by the eighth embodiment of the utility model.

### DETAILED DESCRIPTION OF THE EMBODIMENTS

As described in the background, an epitaxial wafer obtained by using a graphite plate for epitaxial growth has poor performance uniformity. Through research, the inventor found that the reasons for the poor uniformity performance of the epitaxial wafer include at least: in a process of the epitaxial growth, a heating wire directly heats the graphite plate, and the temperature distribution around the graphite plate is uneven, which results in that the substrate in contact with the graphite plate is unevenly heated. An overheated area on the substrate are prone to plastic deformation. It is precisely because of the plastic deformation in the substrate, the performance of the epitaxial wafer obtained by epitaxial growth is not uniform.

In view of this, in accordance with a graphite plate of embodiments of the present application, by providing a heat insulation material at a preset position of the carrying recess, such as a high temperature position, the temperature difference between different positions of the inner wall of the carrying recess is decreased, so that a substrate can be evenly heated.

The technical schemes in the embodiments of the present application will be clearly and completely described below in combination with the accompanying drawings in the embodiments of the present application. Obviously, the described embodiments are only a part of the embodiments of the present application, rather than all the embodiments. Based on the embodiments of the present application, and all other embodiments obtained by those of ordinary skill in the art without creative work shall fall within the protection scope of the present application.

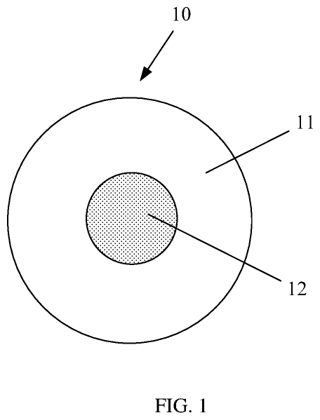

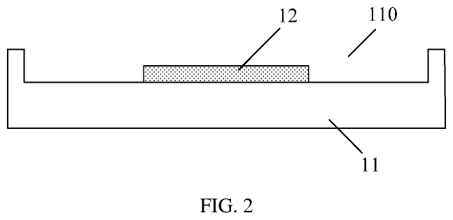

FIG. 1 is a schematic diagram of a structure of a graphite plate provided by the first embodiment of the present application. FIG. 2 is a cross-section diagram of the graphite plate as shown in FIG. 1. Combined with FIG. 1 and FIG. 2, a graphite plate 10 includes a graphite plate body 11, and the graphite plate body 11 includes a carrying recess 110, and at least part of an inner wall of the carrying recess 110 is covered with a heat insulation material 12.

The carrying recess 110 is used for carrying a substrate, and after the substrate is grown with a semiconductor material, a semiconductor epitaxial wafer is obtained. A shape of the carrying recess 110 may be reasonably set according to actual needs. In an embodiment, the carrying recess 110 is a circular recess. Since the substrate is generally in a shape of a disk, the carrying recess 110 is implemented as a circle, so that the shape of the carrying recess 110 may be adapted to the shape of the substrate. And although the graphite plate body 11 shown in FIG. 1 and FIG. 2 is provided with only one carrying recess 110, the number of the carrying recesses 110 on the graphite plate body 11 is not limited thereto, and the number of the carrying recess 110 may be reasonably set according to actual needs. When the graphite plate body 11 is provided with a plurality of carrying recesses 110, in an embodiment, the plurality of carrying recesses 110 are annularly arranged layer by layer with the circle center of the graphite plate body 11 as the center.

A material of the heat insulation material 12 may be selected from any material of which thermal conductivity is lower than that of graphite. In an embodiment, the material of the heat insulation material 12 includes any one of following materials: aluminum oxide, silicon oxide and silicon nitride. A thickness of the heat insulation material 12 may be reasonably set according to actual needs. In an embodiment, the thickness of the heat insulation material ranges from 0.1 micron to 100 microns. In an embodiment, the thickness of the heat insulation material 12 varies in different areas of the inner wall of the carrying recess 110. Since the thickness of the heat insulation material 12 may control the temperature of the corresponding position, by setting the thickness of the heat insulation material 12 on different areas of the inner wall of the carrying recess 110 to be different, thus the various positions of the inner wall of the carrying recess 110 may be better balanced, so that the substrate can be evenly heated.

According to the graphite plate 10 provided by the embodiment, by providing the heat insulation material 12 on at least part of the inner wall of the carrying recess 110, such as the high temperature area of the inner wall of the carrying recess 110, the temperature difference between different positions of the graphite plate may be reduced to balance the temperatures at various positions of the inner wall of the carrying recess 110, so that the substrate can be evenly heated.

In an embodiment, as shown in FIG. 2, a central area of the bottom wall of the carrying recess 110 is covered with the heat insulation material 12. The central area refers to a circular area co-centered with the carrying recess 110, and the area of the central area is not limited in this embodiment. In an embodiment, the thickness of the heat insulation material 12 decreases in the direction along the circle center of the central area to the edge. In an embodiment, the thickness of the heat insulation material 12 increases in the direction along the circle center of the central area to the edge.

Through research, the inventor found that the temperature of the central area of the carrying recess 110 is higher than that of other areas, and the temperature decreases in the direction along the circle center of the central area to the edge. Therefore, by providing the heat insulation material 12 at the central area, and setting the thickness of the heat insulation material 12 to decrease in the direction along the circle center to the edge, it may be more targeted to balance the temperatures at various positions of the inner wall of the carrying recess 110.

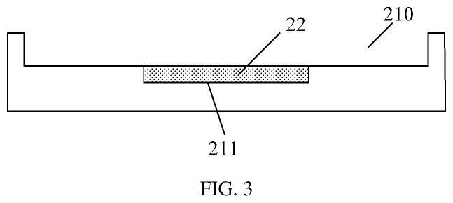

FIG. 3 is a cross-section diagram of a graphite plate provided by the second embodiment of the present application. As shown in FIG. 3, the bottom wall of a carrying recess 210 of a graphite plate 20 includes a recess 211, and the heat insulation material 22 is filled in the recess 211, a surface of the heat insulation material 22 is flush with the bottom wall. Thus, compared with the graphite plate 10 shown in FIG. 1 and FIG. 2, in which the heat insulation material 12 is formed directly on the bottom wall surface, thus the supporting surface of the carrying recess 210 may be ensured to be flat in this embodiment, so as to provide a better support effect.

The recess 211 may be formed at any position of the bottom wall of the carrying recess 210. For example, the recess 211 is located in the central area of the bottom wall of the carrying recess 210. In this case, in an embodiment, the depth of the recess 211 decreases in a direction along the circle center of the central area to the edge, and accordingly, the thickness of the heat insulation material 22 decreases in a direction along the center of the central area to the edge.

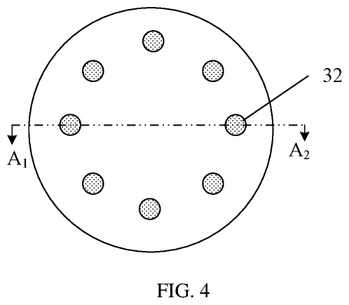

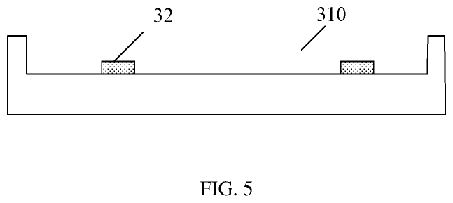

FIG. 4 is a schematic diagram of a structure of a graphite plate provided by the third embodiment of the present application. FIG. 5 is a schematic diagram of the cross-sectional structure of the graphite plate along the line A₁A₂ as shown in FIG. 4. Combined with FIG. 4 and FIG. 5, a bottom wall of a carrying recess 310 is flat, and the central area of the bottom wall includes a plurality of support areas spaced apart from each other, and each of the support areas is covered with a heat insulation material 32.

Specifically, a plurality of areas of the bottom wall of the carrying recess 310 are selected, the plurality of areas spaced apart from each other, and the heat insulation material 32 is formed on each of the areas. Thus, due to the thickness of the heat insulation material 32, a support frame structure is formed on the bottom wall of the carrying recess 310, and the substrate placed in the carrying recess 310 is arranged overhead by the support frame structure, thus avoiding that the corresponding local area of the substrate caused by the central area of the carrying recess 310 is overheated.

The shapes of the plurality of support areas are the same or different. The shape of each of the support areas is selected from any one of circle, triangle, rectangle and polygon. Accordingly, the shapes of the plurality of heat insulation materials 32 are the same or different. The shape of each heat insulation material 32 is selected from any one of cylinder, frustum, cone, cube, and polyhedron. In an embodiment, as shown in FIG. 4, the plurality of support areas are annularly arranged on the bottom wall. Thus, it is possible to ensure that the plurality of heat insulation materials 32 form a stable support frame structure to provide stable support.

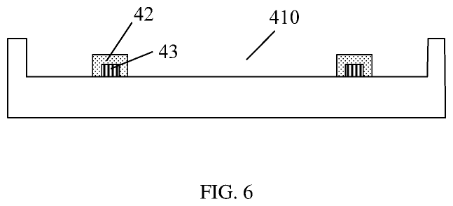

FIG. 6 is a cross-section diagram of a graphite plate provided by the fourth embodiment of the present application. As shown in FIG. 6, the surface of the bottom wall of a carrying recess 410 is flat, and the central area of the bottom wall includes a plurality of support areas spaced apart from each other, and each of the support areas is provided with a protrusion 43, and the protrusion 43 is covered with a heat insulation material 42.

Specifically, a plurality of areas spaced apart from each other are selected on the bottom wall of the carrying recess 410, each of the areas is provided with the protrusion 43, and the heat insulation material 42 is formed on each of the protrusions 43, and the heat insulation material 42 may be provided only on the surface of the protrusion 43, or may cover the entire protrusion 43. By providing the protrusions 43 with the heat insulation material 42, a support frame structure may be formed on the bottom wall of the carrying recess 410, and the substrate placed in the carrying recess 410 is arranged overhead by the support frame structure, thus avoiding overheated of the corresponding local area of the substrate caused by the central area of the carrying recess 410.

In an embodiment, the heights of the plurality of protrusions 43 on the plurality of support areas are not equal, and correspondingly, and the thicknesses of the heat insulation materials 42 on the plurality of protrusions 43 are not equal. The sum of the height of the protrusion 43 and the thickness of the heat insulation material 42 on each of the support areas is equal to that of others

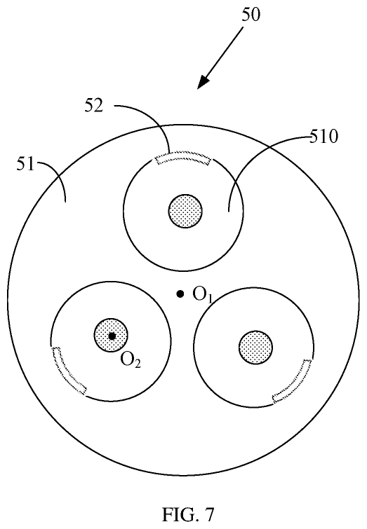

FIG. 7 is a cross-section diagram of a graphite plate provided by the fifth embodiment of the present application. As shown in FIG. 7, the difference between a graphite plate 50 and the graphite plate provided by any of the above embodiments is that at least part of the sidewall of the carrying recess 510 is also covered with the heat insulation material 52.

In an embodiment, a part of the sidewall of the carrying recess 510 away from a center of the graphite plate body 51 is covered with the heat insulation material 52. During the rotation of the graphite plate 50, the substrate located in the carrying recess 510 is subjected to centrifugal force, so that the edge region of the substrate away from the center of the graphite plate body 51 is always in contact with the inner wall of the carrying recess 510, which tends to cause higher temperature at the contact position than at other positions of the sidewall of the substrate. Therefore, by providing the heat insulation material 52 on the sidewall, the heating of the substrate may be further balanced, thereby improving the performance uniformity of the epitaxial wafer.

The thickness of the heat insulation material 52 on the sidewall of the carrying recess 510 may be equal or different at various positions. In an embodiment, the thickness of the heat insulation material 52 on the sidewall of the carrying recess 510 increases first and then decreases along the circumferential direction. Thus, by reasonably setting the position of the heat insulation material 52 on the sidewall of the carrying recess 510, for example, the heat insulation material 52 can be disposed on the extension line of the connection between the center point O1 of the graphite plate body 51 and the center point O2 of the carrying recess 510, so that the substrate is in contact with the area where the thickness of the heat insulation material 52 is the greatest.

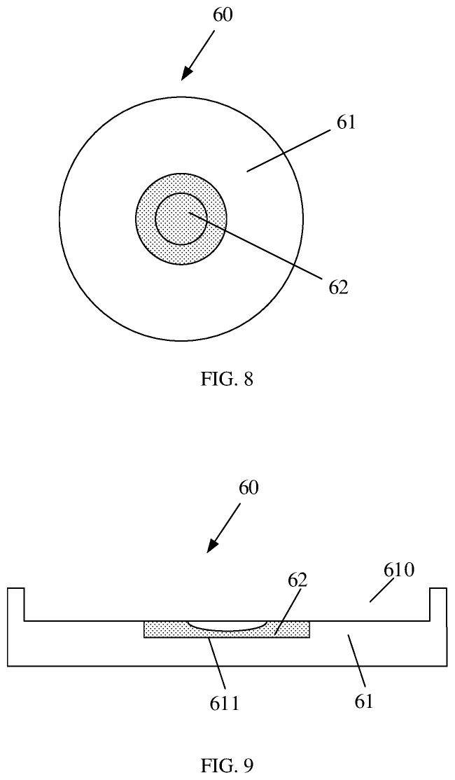

FIG. 8 is a schematic diagram of a structure of a graphite plate provided by the sixth embodiment of the utility model. FIG. 9 is a sectional view of the graphite plate as shown in FIG. 8. As shown in FIG. 8 and FIG. 9, a graphite plate 60 includes a graphite plate body 61 and a heat insulation material 62. A bottom wall of a carrying recess 610 of a graphite plate 60 includes a recess 611, a bottom surface of the recess 611 is covered with the heat insulation material 62, and a surface of the heat insulation material 62 is not higher than a surface of the bottom wall. At least part of the surface of the heat insulation material 62 is lower than the surface of the bottom wall. A height of the surface of the heat insulation material 62 increases in a direction along the center of the central area to an edge.

In an embodiment, a part of the surface of the heat insulation material 62 is lower than the bottom wall of the carrying recess 610, and the other part of the surface is flush with the bottom wall of the carrying recess 610. That is, the surface of the heat insulation material 62 includes a recessed area, the recessed area may be circular in shape, and the center of the recessed area coincides with the center of the carrying recess 610. A height of the surface of the recessed area increases in the direction along the center of the central area to an edge, correspondingly, a thickness of the heat insulation material 62 increases. More specifically, the height of the surface of the recessed area first increases and then remains unchanged in the direction along the circle center of the central area to an edge. Correspondingly, the thickness of the heat insulation material 62 increases first and then remains unchanged.

In another embodiment, the height of the surface of the recessed area gradually increases, and correspondingly, the thickness of the heat insulation material 62 gradually increases in the direction along the circle center of the central area to the edge.

In this embodiment, when a substrate is placed in the carrying recess 610, the substrate is supported by the bottom wall and an area where the heat insulation material 62 is flush with the bottom wall, and the recessed area of the heat insulation material 62 is not in direct contact with the substrate, so that an empty space is formed between the substrate and the heat insulation material 62. Because the heat conductivity coefficient of air is small, this structure may further reduce heat-conducting capabilities of the central area, thereby reducing a temperature of the central area. And, the thicknesses of the heat insulation materials 62 of different areas are different by adjusting the thickness of the heat insulation material 62, so that the temperature of the central area everywhere can be adjusted differently, so as to better ensure that the substrate can be evenly heated. In addition, the volume of the heat insulation material 62 in this embodiment is relatively small, which can reduce the production cost of the graphite plate 60.

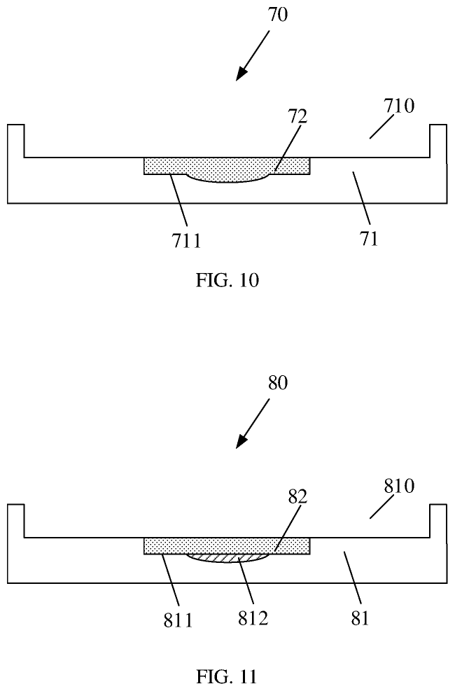

FIG. 10 is a sectional view of a graphite plate provided by the seventh embodiment of the utility model. As shown in FIG. 10, a graphite plate 70 includes a graphite plate body 71 and a heat insulation material 72. A bottom wall of a carrying recess 710 of the graphite plate 70 includes a recess 711, a heat insulation material 72 is filled in the recess 711, and a depth of the recess 711 decreases in a direction along the circle center of the central area to an edge, correspondingly, a thickness of the heat insulation material 72 decreases in the direction along the center of the central area to an edge. More specifically, a depth of the recess 711 first decreases and then remains unchanged in the direction along the center of the central area to an edge, and correspondingly, a thickness of the heat insulation material 72 first decreases and then remains unchanged.

In this embodiment, the thickness of the heat insulation material 72 decreases in the direction along the center of the central area to an edge, the structure may further reduce heat-conducting capabilities of the central area, thereby reducing the temperature of the central area. In this embodiment, a downward recessed area is provided in the recess 711, so that the depths of different positions in the recess 711 are different. More specifically, the depth of the recess 711 gradually decreases in the direction along the center of the central area to an edge. Correspondingly, the thickness of the heat insulation material 72 filled in the recess 711 gradually decreases in the direction along the center of the central area to an edge. At the center of the central area, the thickness of the heat insulation material 72 is the thickest and thermal conductivity is the worst, the thickness of the heat insulation material 72 decreases and thermal conductivity increases gradually in the direction along the center of the central area to an edge, this structure may make different adjustments to the temperature in the central area everywhere, so as to better ensure that the substrate can be evenly heated.

FIG. 11 is a sectional view of a graphite plate provided by the eighth embodiment of the utility model. As shown in FIG. 11, a graphite plate 80 includes a graphite plate body 81 and a heat insulation material 82. A bottom wall of a carrying recess 810 of the graphite plate 80 includes a recess 811, a depth of the recess 811 decreases in a direction along the center of the central area to an edge, and the heat insulation material 82 is filled in a part of the recess 811. Specifically, the bottom of the recess 811 is recessed downward, and there is a dielectric material 812 between the bottom of the recess 811 and the heat insulation material 82. The dielectric material 812 may be a filler or a coating. When the dielectric material 812 is a filler, the dielectric material 812 may be an insulation board or foam, or the like. When the dielectric material 812 is a coating, it may be a different material from that of the heat insulation material 82, and specifically, a material of the dielectric material 812 may be a material with a heat conductivity coefficient smaller than that of the heat insulation material 82. The distance from the bottom of the recess 811 to the heat insulation material 82 gradually decreases in the direction along the center of the central area to an edge, and correspondingly, a thickness of the dielectric material 812 gradually decreases.

In this embodiment, because the heat conductivity coefficient of the dielectric material is small, this structure can further reduce heat-conducting capabilities of the central area, thereby reducing the temperature of the central area. In this embodiment, the dielectric material and the heat insulation material are provided in the recess, and the thickness of the dielectric material gradually decreases in the direction along the center of the central region to an edge. This structure may make different adjustments to the temperature in the central area everywhere, the heat conduction performance is the worst at the center of the central area, and the heat conduction performance gradually is improved in the direction along the center of the central region to an edge, so as to better ensure that the substrate can be evenly heated.

The above descriptions are only preferred embodiments of the present application, and are not intended to limit the present application. Any modifications, equivalent replacements, or the like, made within the spirit and principles of the present application shall fall within the protection scope of the present application.

What is claimed is:

1. A graphite plate, comprising:
a graphite plate body, wherein the graphite plate body comprises a carrying recess, and at least part of an inner wall of the carrying recess is covered with a heat insulation material.

2. The graphite plate according to claim 1, wherein a central area of a bottom wall of the carrying recess is covered with the heat insulation material.

3. The graphite plate according to claim 2, wherein a thickness of the heat insulation material decreases in a direction along a center of the central area to an edge.

4. The graphite plate according to claim 2, wherein a thickness of the heat insulation material increases in a direction along a center of the central area to an edge.

5. The graphite plate according to claim 2, wherein the bottom wall comprises a recess, a depth of the recess decreases in a direction along a center of the central area to an edge, and a dielectric layer is provided between a bottom of the recess and the heat insulation material.

6. The graphite plate according to claim 2, wherein the bottom wall comprises a recess, the heat insulation material is filled in the recess, and a surface of the heat insulation material is not higher than the bottom wall.

7. The graphite plate according to claim 6, wherein a surface of the heat insulation material is flush with the bottom wall.

8. The graphite plate according to claim 6, wherein a height of a surface of the heat insulation material increases in a direction along a center of the central area to an edge.

9. The graphite plate according to claim 6, wherein a depth of the recess decreases in a direction along a center of the central area to an edge.

10. The graphite plate according to claim 1, wherein a bottom wall of the carrying recess is flat, the central area of the bottom wall comprises a plurality of support areas spaced apart from each other, and each of the support areas is covered with the heat insulation material.

11. The graphite plate according to claim 10, wherein each of the support areas is provided with a protrusion, and the protrusion is covered with the heat insulation material.

12. The graphite plate according to claim 10, wherein the plurality of support areas are annularly arranged on the bottom wall.

13. The graphite plate according to claim 1, wherein at least part of sidewall of the carrying recess is covered with the heat insulation material.

14. The graphite plate according to claim 13, wherein a part of the sidewall of the carrying recess away from a center of the graphite plate body is covered with the heat insulation material.

15. The graphite plate according to claim 13, wherein a thickness of the heat insulation material first increases and then decreases along a circumferential direction.

16. The graphite plate according to claim 1, wherein a thickness of the heat insulation material ranges from 0.1 micron to 100 microns.

17. The graphite plate according to claim 1, wherein a material of the heat insulation material comprises any one of following materials: aluminum oxide, silicon oxide and silicon nitride.

18. The graphite plate according to claim 1, wherein a thickness of the heat insulation material at different areas of an inner wall of the carrying recess is different.
